(19) United States
(12) Patent Application Publication
(10) Pub. No.: US 2006/0186419 A1
(43) Pub. Date: Aug. 24, 2006

(54) Light-emitting device

(76) Inventors: Satoshi Mikoshiba, Yamato-shi (JP); Hidesato Saruwatari, Kawasaki-shi (JP); Takashi Kuboki, Tokyo (JP); Norio Takami, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/345,527

(22) Filed: Feb. 2, 2006

(30) Foreign Application Priority Data
Feb. 4, 2005 (JP) 2005-029130

(51) Int. Cl. H01L 33/00; H01L 31/12; H01L 27/15; H01L 29/26

(52) U.S. Cl. 257/79

(57) ABSTRACT

A light-emitting device includes a first electrode, a second electrode, a porous layer and an electrolyte. The first electrode comprises a first surface. The second electrode comprises a second surface. The porous layer is formed of n-type semiconductor and provided on the first surface of the first electrode or the second surface of the second electrode. The electrolyte is provided between the first surface of the first electrode and the second surface of the second electrode. The electrolyte electrically contacts the first electrode and second electrode. The electrolyte contains a molten salt and a luminous dye containing Ru. The molten salt contains an anion component and a cation component having a structure represented by the following formula (A).

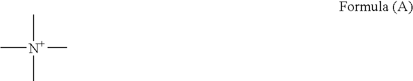

### CROSS-REFERENCE TO RELATED APPLICATIONS

This application is based upon and claims the benefit of priority from prior Japanese Patent Application No. 2005-029130, filed Feb. 4, 2005, the entire contents of which are incorporated herein by reference.

### BACKGROUND OF THE INVENTION

1. Field of the Invention

The present invention relates to a light-emitting device.

2. Description of the Related Art

A light-emitting device making use of an electrochemical reaction has been known for more than 30 years. A light-emitting material in an electrolyte is partly oxidized on a positive (+) pole, and partly reduced on a negative (−) pole. An oxidized substance formed by the oxidation reaction, and a reduced substance formed by the reduction reaction collide with each other in an electrolyte layer and emit light, and each substance returns to an original light-emitting material. By making use of this principle, a device enhanced in light-emitting efficiency by introducing a porous layer into the device was disclosed on page 310 of Collected Papers of Electrochemical Society Meeting in 2004 (Mar. 24, 2004).

According to the study by Seiichi Okamoto, et al. at Life Science and Systems Engineering of Kyushu Institute of Technology Graduate School, an electrochemical light-emitting device in which the electrochemiluminescence is increased by using a nano-porous TiO₂ electrode is disclosed. A nano-porous TiO₂ layer is formed on a SnO₂/F transparent conductive film formed on a glass substrate, and the obtained electrode is used as a cathode of this electrochemical light-emitting device. Aluminum is evaporated to an outer surface of the glass substrate of the cathode, and the obtained aluminum layer is used as a reflective film. As a counter electrode, a SnO₂/F transparent conductive glass is used. As an electrolysis solution, a solution obtained by dissolving a ruthenium complex in acetonitrile is employed. By using such an electrochemical light-emitting device, it is reported that the emission luminance is outstandingly improved as compared with the case using no nano-porous TiO₂ layer.

However, the electrochemical light-emitting device reported in the publication is short in half-life of light intensity, that is, short in life.

On the other hand, Jpn. Pat. Appln. KOKAI Publication No. 2002-203681 describes problems of elements containing transition metal complex such as elements containing ruthenium complex, that is, low emission luminance, slow response speed, and poor durability, although the driving voltage is low. Jpn. Pat. Appln. KOKAI Publication No. 2002-203681 improves these problems by adding an electrolyte to an organic compound layer interposed between a pair of electrodes and containing transition metal complex. For example, molten salt is used as the electrolyte. Jpn. Pat. Appln. KOKAI Publication No. 2002-203681 discloses that the driving voltage of this light-emitting device is 4V to 5V.

### BRIEF SUMMARY OF THE INVENTION

An object of the present invention is to provide a light-emitting device of long life.

According to a first aspect of the present invention, there is provided a light-emitting device comprising:

a first electrode comprising a first surface;

a second electrode comprising a second surface;

a porous layer formed of n-type semiconductor and provided on the first surface of the first electrode or the second surface of the second electrode; and

an electrolyte containing: a luminous dye containing Ru; and a molten salt including an anion component and a cation component having a structure represented by the following formula (A), the electrolyte provided between the first surface of the first electrode and the second surface of the second electrode, the electrolyte electrically contacting the first electrode and the second electrode.

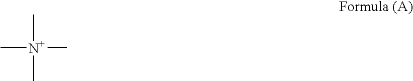

According to a second aspect of the present invention, there is provided a light-emitting device comprising:

a first electrode comprising a first surface;

a porous layer provided on the first surface of the first electrode;

a second electrode comprising a second surface, the second surface facing the porous layer; and

an electrolyte provided between the porous layer and the second surface of the second electrode, the electrolyte electrically contacting the first electrode and the second electrode, and the electrolyte containing a luminous dye,

wherein either the first electrode or second electrode is formed of a metal-containing substrate.

According to a third aspect of the present invention, there is provided a light-emitting device comprising:

a film container;

a first electrode provided in the container and comprising a first surface;

a second electrode comprising a second surface; and

an electrolyte containing: a luminous dye; and a molten salt including an anion component and a cation component having a structure represented by the following formula (A), the electrolyte provided between the first surface of the first electrode and the second surface of the second electrode, the electrolyte electrically contacting the first electrode and the second electrode.

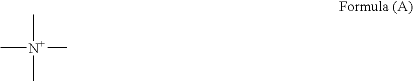

According to a fourth aspect of the present invention, there is provided a light-emitting device comprising:

a film container;

a first electrode provided in the film container and comprising a first surface;

a porous layer provided on the first surface of the first electrode;

a second electrode comprising a second surface, the second surface facing the porous layer; and

an electrolyte provided between the porous layer and the second surface of the second electrode, the electrolyte electrically contacting the first electrode and the second electrode, and the electrolyte containing a luminous dye,

wherein either the first electrode or second electrode is formed of a metal-containing substrate.

### BRIEF DESCRIPTION OF THE SEVERAL VIEWS OF THE DRAWING

FIG. 1 is a schematic perspective view showing first and second light-emitting devices according to an embodiment of the invention;

FIG. 2 is a sectional view taken along line II-II of the light-emitting device in FIG. 1;

FIG. 3 is a schematic sectional view showing the light-emitting device according to another embodiment of the invention;

FIG. 4 is a schematic plan view showing a combshaped electrode assembled in the light-emitting device in FIG. 3; and

FIG. 5 is a schematic sectional view showing the light-emitting device according to still another embodiment of the invention.

### DETAILED DESCRIPTION OF THE INVENTION

As a result of intensive studies in order to obtain a light-emitting device of long life, the present inventors have discovered that, when a porous layer is formed of n-type semiconductor and a luminous dye contains Ru, an oxidation and reduction reaction of a dye is caused even if a low voltage is applied, and decomposition of the electrolyte can be suppressed, whereby reversibility of the oxidation and reduction reaction of the dye can be enhanced, and the life of a light-emitting device is extended.

That is, a first light-emitting device according to a first embodiment of the invention comprising:

a first electrode comprising a first surface;

a second electrode comprising a second surface;

a porous layer formed of n-type semiconductor and provided on the first surface of the first electrode or the second surface of the second electrode; and

an electrolyte provided between the first surface of the first electrode and the second surface of the second electrode, the electrolyte electrically contacting the first electrode and the second electrode.

The electrolyte contains:

a molten salt including an anion component and a cation component having a structure represented by the following formula (A); and

a luminous dye containing Ru.

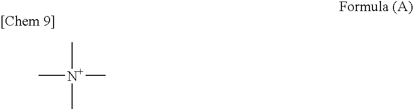

In the first light-emitting device, the first electrode and the second electrode may be arranged opposite to each other across an interval, and the first electrode may be arranged on an insulating substrate, and the second electrode may be arranged on the insulating substrate away from the first electrode.

A second light-emitting device according to a second embodiment of the invention comprising:

a first electrode comprising a first surface;

a porous layer provided on the first surface of the first electrode;

a second electrode comprising a second surface, the second surface facing the porous layer; and

an electrolyte provided between the porous layer and the second surface of the second electrode, the electrolyte electrically contacting the first electrode and the second electrode, and the electrolyte containing a luminous dye.

Either the first electrode or the second electrode is formed of a metal-containing substrate. Examples of the metal-containing substrate include a metal substrate and an alloy substrate.

According to the second light-emitting device, either the first electrode or the second electrode is formed of metal or alloy. Therefore, the internal resistance of the light-emitting device is lowered and the light emission efficiency is enhanced, so that luminous intensity can be enhanced.

Further, a third light-emitting device according to a third embodiment of the invention comprising:

a film container;

a first electrode provided in the container and comprising a first surface;

a second electrode comprising a second surface; and

an electrolyte provided between the first surface of the first electrode and the second surface of the second electrode, the electrolyte electrically contacting the first electrode and the second electrode.

The electrolyte contains:

a molten salt including an anion component and a cation component having a structure represented by the above formula (A); and

a luminous dye.

According to the third light-emitting device, since the light-emitting device can be enclosed in the film container, a sealing member for sealing the electrolyte between the first electrode and the second electrode is not needed. As a result, dissolving of the sealing member into the electrolyte can be prevented. Accordingly, it is possible to suppress deterioration of the luminous dye in the electrolyte, and a light-emitting device of high luminous intensity and long life is realized.

In the third light-emitting device, the first electrode and the second electrode may be arranged opposite to each other across an interval, and the first electrode may be arranged on an insulating substrate, and the second electrode may be arranged on the insulating substrate away from the first electrode.

A fourth light-emitting device according to a fourth embodiment of the invention comprising:

a film container;

a first electrode provided in the film container and comprising a first surface;

a porous layer provided on the first surface of the first electrode;

a second electrode comprising a second surface, the second surface facing the porous layer; and

an electrolyte provided between the porous layer and the second surface of the second electrode, the electrolyte electrically contacting the first electrode and the second electrode, and the electrolyte containing a luminous dye.

Either the first electrode or the second electrode is formed of a metal-containing substrate. Examples of the metal-containing substrate include a metal substrate and an alloy substrate.

According to the fourth light-emitting device, since the light-emitting device can be enclosed in the film container, a sealing member for sealing the electrolyte between the first electrode and the second electrode is not needed. As a result, dissolving of the sealing member into electrolyte can be prevented. Accordingly, it is possible to suppress deterioration of the luminous dye in the electrolyte, and a light-emitting device of high luminous intensity and long life is realized.

First, the first light-emitting device will be explained.

The first light-emitting device has at least two electrodes, that is, a first electrode and a second electrode. The first and second electrodes are arranged in one cell, and are electrically insulated from each other. For example, the first electrode and the second electrode may be arranged on a same insulated substrate, or the first electrode and the second electrode may be arranged opposite to each other across a desired distance.

A porous layer may not be provided in the first electrode and the second electrode, but when the porous layer is formed in at least one of the first electrode and the second electrode, the luminous intensity can be further enhanced.

The first electrode, the second electrode, the porous layer, and the electrolyte will be specifically described below.

(First Electrode and Second Electrode)

A first method will be explained. As the first electrode and the second electrode, both may be transparent electrodes, or alternatively, one may be formed of a carbon sheet, a metal substrate or an alloy substrate, and the other may be formed of a transparent electrode. The carbon sheet is not particularly limited as far as a carbon material work as a conductive component. As the metal substrate and the alloy substrate, the materials explained below about the second light-emitting device can be used. As a result, the luminous intensity can be enhanced.

The transparent electrode is preferred to have a transparent conductive film small in absorption in visible region and having conductivity. The transparent conductive film is preferably a tin oxide film doped with fluorine or indium, or a zinc oxide film doped with fluorine or indium. From the viewpoint of enhancing the conductivity and preventing elevation of resistance, it is desired to arrange a metal matrix of low resistance together with the transparent electrode.

In another method, the first electrode and the second electrode are arranged on a same insulated substrate. At this time, the same substrate as in the first method may be used as the wiring. The electrodes can be comb-shaped electrodes. In this case, the first electrode and second electrode may be arranged alternately. The substrate opposite to the insulating substrate between the first electrode and the second electrode may be a transparent substrate having no conductivity.

(Support Substrate)

The transparent electrode is preferred to further have a support substrate for carrying the transparent conductive film. In order that the surface of the support substrate opposite to the surface having the transparent conductive film formed thereon functions as a light-emitting surface, the support substrate is preferred to be made of a transparent substrate small in absorption in visible region, such as a glass or a plastic substrate.

(Porous Layer)

The porous layer may be formed of, for example, a conductor such as metal or alloy, a semiconductor, or an insulator. In particular, an n-type semiconductor such as titania is most preferable. By the n-type semiconductor such as titania, a dye can exchange electrons smoothly not only with the first or second electrode, but also with the porous layer, and therefore, the luminous intensity is higher as compared with the case of using an insulator such as alumina.

Examples of metal include aluminum, nickel, iron, gold, platinum, and silver. Alloy may include at least one metal selected from the group consisting aluminum, nickel, iron, gold, platinum, and silver.

The semiconductor is, for example, a transparent semiconductor small in absorption in visible region. As such a semiconductor, a metal oxide semiconductor is preferable. Specific examples thereof include oxides of transition metals such as titanium, zirconium, hafnium, strontium, zinc, indium, yttrium, lanthanum, vanadium, niobium, tantalum, chromium, molybdenum, and tungsten, perovskites such as SrTiO₃, CaTiO₃, BaTiO₃, MgTiO₃, and SrNb₂O₆, these composite oxides or mixtures of oxides, and GaN.

As the insulator, for example, alumina or silica can be used.

(Electrolyte)

The electrolyte electrically contacts with the first electrode and the second electrode. The electrolyte contains: a molten salt including a cation component having a structure represented by the following formula (A) and an anion component; and a luminous dye having a reversible oxidation-reduction function.

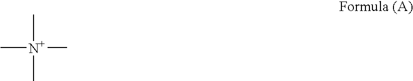

The luminous dye is not particularly limited, but is desired to be a phosphor dye. Such a phosphor dye is preferred to be a complex having heavy metal. Usable heavy metals are Ir, Tb, Yb, Nd, Er, Ru, Os, Re and the like. The heavy metal in the complex may be either one type or two or more types. A ligand is a pyridine derivative, a bipyridyl derivative, a terpyridyl derivative, a phenanthrone derivative, a quinoline derivative, an acetyl acetone derivative, a dicarbonyl compound derivative, etc. In particular, a complex having Ru in central metal is desired. As a result, a higher luminous intensity is realized.

The molten salt having a cation component represented by the above formula (A) is preferred to be an ionic liquid not having vapor pressure at room temperature. The structure is not particularly limited, but the cation component may be an imidazolium salt, a pyridinium salt, a quaternary ammonium salt, etc. In particular, an imidazolium salt is preferred because a long life is obtained.

The cation is desired to be at least one type selected from six types of cation represented by the following chemical formulas 1 to 6. In particular, formula 2 is preferred. A compound in formula 2 is preferred because the viscosity is low, diffusion of dye is smooth, and an electrochemical reaction is hence high in speed.

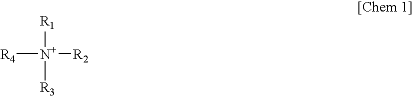

Specific examples of the cation represented by the above formula 1 will be given below.

R₁, R₂, R₃, and R₄ for composing the cation shown in the above formula 1 may be either same or mutually different, including an alkyl group, a phenyl group, a benzyl group, or a substituent containing C, H and O. In particular, an alkyl group, a phenyl group, and a benzyl group are preferred. Among substituents containing carbon, hydrogen and oxygen, an alkyl group is preferred. At least one substituent of R₁, R₂, R₃, and R₄ is preferred to be a phenyl group or benzyl group. The number of carbon atoms is limited to 8 or less because, if exceeding 8, viscosity of the molten salt is increased, and ion diffusion performance of the electrolyte may be lowered. A more preferred range of the number of carbon atoms is 1 to 4.

(1) Examples of a cation of which R₁, R₂, R₃, and R₄ are alkyl groups with 8 or less carbon atoms include N,N,N,N-tetramethyl ammonium ion, N,N,N-trimethyl ethyl ammonium ion, N,N,N-trimethyl propyl ammonium ion, N,N,N-trimethyl isopropyl ammonium ion, N,N,N-trimethyl butyl ammonium ion, N,N,N-trimethyl isobutyl ammonium ion, N,N,N-trimethyl-sec-butyl ammonium ion, N,N,N-trimethyl-tert-butyl ammonium ion, N,N,N-trimethyl pentyl ammonium ion, N,N,N-trimethyl isopentyl ammonium ion, N,N,N-trimethyl neopentyl ammonium ion, N,N,N-trimethyl-tert-pentyl ammonium ion, N,N,N-trimethyl-(2-methylbutyl)ammonium ion, N,N,N-trimethyl hexyl ammonium ion, N,N,N-trimethyl heptyl ammonium ion, N,N,N-trimethyl octyl ammonium ion, N,N-diethyl-N,N-dimethyl ammonium ion, N-ethyl-N,N-dimethyl propyl ammonium ion, N-ethyl-N,N-dimethyl isopropyl ammonium ion, N-ethyl-N,N-dimethyl butyl ammonium ion, N-ethyl-N,N-dimethyl isobutyl ammonium ion, N-ethyl-N,N-dimethyl-sec-butyl ammonium ion, N-ethyl-N,N-dimethyl-tert-butyl ammonium ion, N-ethyl-N,N-dimethyl pentyl ammonium ion, N,N-dimethyl-N,N-dipropyl ammonium ion, N,N-dimethyl-N-propyl-N-isopropyl ammonium ion, N,N-dimethyl-N,N-diisopropyl ammonium ion, N,N-dimethyl-N-propyl butyl ammonium ion, N,N-dimethyl-N-isopropyl butyl ammonium ion, N,N,N-triethyl-N-methyl ammonium ion, N,N-diethyl-N-methyl propyl ammonium ion, N,N-diethyl-N-methyl isopropyl ammonium ion, N,N-diethyl-N-methyl butyl ammonium ion, N,N-diethyl-N-methyl isobutyl ammonium ion, N,N-diethyl-N-methyl-sec-butyl ammonium ion, N,N-diethyl-N-methyl-tert-butyl ammonium ion, N,N-diethyl-N-methyl pentyl ammonium ion, N-ethyl-N-methyl-N,N-dipropyl ammonium ion, N-ethyl-N-methyl-N-propyl-N-isopropyl ammonium ion, N-ethyl-N-methyl-N,N-diisopropyl ammonium ion, N-ethyl-N-methyl-N-propyl butyl ammonium ion, N-ethyl-N-methyl-N-propyl isobutyl ammonium ion, N-ethyl-N-methyl-N-propyl-sec-butyl ammonium ion, N-ethyl-N-methyl-N-propyl-tert-butyl ammonium ion, N-ethyl-N-methyl-N-isopropyl butyl ammonium ion, N-ethyl-N-methyl-N-isopropyl isobutyl ammonium ion, N-ethyl-N-methyl-N-isopropyl-sec-butyl ammonium ion, N-ethyl-N-methyl-N-isopropyl-tert-butyl ammonium ion, N,N,N,N-tetraethyl ammonium ion, N,N,N-triethyl propyl ammonium ion, N,N,N-triethyl isopropyl ammonium ion, N,N,N-triethyl butyl ammonium ion, N,N,N-triethyl-sec-butyl ammonium ion, N,N,N-triethyl-tert-butyl ammonium ion, N,N-diethyl-N,N-dipropyl ammonium ion, N,N-diethyl-N-propyl-N-isopropyl ammonium ion, N,N-diethyl-N,N-diisopropyl ammonium ion, N,N-diethyl-N-propyl butyl ammonium ion, N,N-diethyl-N-isopropyl butyl ammonium ion, N,N,N,N-tetrapropyl ammonium ion, and N,N,N,N-tetrabutyl ammonium ion.

(2) Examples of a cation of which R₁, R₂, R₃, and R₄ are phenyl groups with 8 or less carbon atoms include N,N,N-trimethyl anilinium ion, N-ethyl-N,N-dimethyl anilinium ion, N,N-dimethyl-N-propyl anilinium ion, N,N-dimethyl-N-isopropyl anilinium ion, N,N-diethyl-N-methyl anilinium ion, N-ethyl-N-methyl-N-propyl anilinium ion, N-ethyl-N-methyl-N-isopropyl anilinium ion, N-methyl-N,N-dipropyl anilinium ion, N-methyl-N-propyl-N-isopropyl anilinium ion, N-methyl-N,N-diisopropyl anilinium ion, N,N,N-triethyl anilinium ion, N,N-diethyl-N-propyl anilinium ion, N,N-diethyl-N-isopropyl anilinium ion, N-butyl-N,N-dimethyl anilinium ion, N,N-dimethyl-N-pentyl anilinium ion, N-hexyl-N,N-dimethyl anilinium ion, N-heptyl-N,N-dimethyl anilinium ion, N,N-dimethyl-N-octyl anilinium ion, N,N,N-trimethyl toluidinium ion, N,N-dimethyl-N-propyl toluidinium ion, N,N-dimethyl-N-isopropyl toluidinium ion, N,N-diethyl-N-methyl toluidinium ion, N-ethyl-N-methyl-N-propyl toluidinium ion, N-ethyl-N-methyl-N-isopropyl toluidinium ion, N-methyl-N,N-dipropyl toluidinium ion, N-ethyl-N-methyl-N-propyl-N-isopropyl toluidinium ion, N-methyl-N,N-diisopropyl toluidinium ion, N,N,N-triethyl toluidinium ion, N,N-diethyl-N-propyl toluidinium ion, N,N-diethyl-N-isopropyl toluidinium ion, and N-butyl-N,N-dimethyl toluidinium ion.

(3) Examples of a cation of which R₁, R₂, R₃, and R₄ are benzyl groups with 8 or less carbon atoms include N,N,N-trimethyl benzyl ammonium ion, N-ethyl-N,N-dimethyl benzyl ammonium ion, N,N-dimethyl-N-propyl benzyl ammonium ion, N,N-dimethyl-N-isopropyl benzyl ammonium ion, N,N-diethyl-N-methyl benzyl ammonium ion, N-ethyl-N-methyl-N-propyl benzyl ammonium ion, N-ethyl-N-methyl-N-isopropyl benzyl ammonium ion, N-methyl-N,N-dipropyl benzyl ammonium ion, N-methyl-N-propyl-N-isopropyl benzyl ammonium ion, N-methyl-N,N-diisopropyl benzyl ammonium ion, N,N,N-triethyl benzyl ammonium ion, N,N-diethyl-N-propyl benzyl ammonium ion, N,N-diethyl-N-isopropyl benzyl ammonium ion, N-butyl-N,N-dimethyl benzyl ammonium ion, N,N-dimethyl-N-pentyl benzyl ammonium ion, N-hexyl-N,N-dimethyl benzyl ammonium ion, N-heptyl-N,N-dimethyl benzyl ammonium ion, and N,N-dimethyl-N-octyl benzyl ammonium ion.

(4) Examples of a cation of which R₁, R₂, R₃, and R₄ are substituents containing carbon, hydrogen and oxygen with 8 or less carbon atoms include 2-methoxy-N,N,N-trimethyl ethyl ammonium ion, 2-ethoxy-N,N,N-trimethyl ethyl ammonium ion, 2-propoxy-N,N,N-trimethyl ethyl ammonium ion, 2-isopropoxy-N,N,N-trimethyl ethyl ammonium ion, 2-methoxy-N-ethyl-N,N-dimethyl ethyl ammonium ion, N-(2-methoxy ethyl)-N,N-dimethyl propyl ammonium ion, N-(2-methoxy ethyl)-N,N-dimethyl butyl ammonium ion, N-(2-methoxy ethyl)-N,N-dimethyl pentyl ammonium ion, N-(2-methoxy ethyl)-N,N-dimethyl hexyl ammonium ion, N-(2-methoxy ethyl)-N,N-dimethyl heptyl ammonium ion, N-(2-methoxy ethyl)-N,N-dimethyl octyl ammonium ion, 2-ethoxy-N-ethyl-N,N-dimethyl ethyl ammonium ion, 2-propoxy-N-ethyl-N,N-dimethyl ethyl ammonium ion, 2-isopropoxy-N-ethyl-N,N-dimethyl ethyl ammonium ion, N,N,N-trimethyl anisidinium ion, N-ethyl-N,N-dimethyl anisidinium ion, N,N-dimethyl-N-propyl anisidinium ion, N,N-dimethyl-N-isopropyl anisidinium ion, N,N-diethyl-N-methyl anisidinium ion, N-ethyl-N-methyl-N-propyl anisidinium ion, N-ethyl-N-methyl-N-isopropyl anisidinium ion, N-methyl-N,N-dipropyl anisidinium ion, N-methyl-N-propyl-N-isopropyl anisidinium ion, N-methyl-N,N-diisopropyl anisidinium ion, N,N,N-triethyl anisidinium ion, N,N-diethyl-N-propyl anisidinium ion, N,N-diethyl-N-isopropyl anisidinium ion, N-butyl-N,N-dimethyl anisidinium ion, N,N-dimethyl-N-pentyl anisidinium ion, N-hexyl-N,N-dimethyl anisidinium ion, N-heptyl-N,N-dimethyl anisidinium ion, and N,N-dimethyl-N-octyl anisidinium ion.

Among them, N,N,N-trimethyl butyl ammonium ion, N-ethyl-N,N-dimethyl propyl ammonium ion, N-ethyl-N,N-dimethyl butyl ammonium ion, and N,N-dimethyl-N-propyl butyl ammonium ion are particularly preferred.

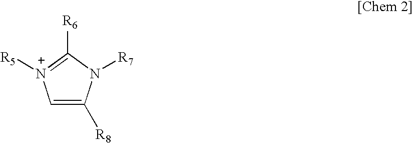

R₅, R₆, R₇, and R₈ for composing the cation shown in the above formula 2 may be either same or mutually different, including an alkyl group, a substituent containing C, H and O, or a hydrogen atom. In particular, an alkyl group is preferred. Among substituents containing carbon, hydrogen and oxygen, an alkyl group is preferred. The number of carbon atoms is limited to 8 or less because, if exceeding 8, viscosity of the molten salt is increased, and ion diffusion performance of the electrolyte may be lowered. A more preferred range of the number of carbon atoms is 1 to 4 in R₅ and R₇, and 0 to 2 in R₆ and R₈. Zero carbon atoms means hydrogen.

Specific examples of the cation represented by the formula 2 will be given below.

(1) Examples of a cation of which R₅ and R₇ are alkyl groups with 8 or less carbon atoms, and of which R₆ and R₈ are hydrogen include 1,3-dimethyl imidazolium ion, 1-ethyl-3-methyl imidazolium ion, 1-methyl-3-propyl imidazolium ion, 1-methyl-3-isopropyl imidazolium ion, 1-butyl-3-methyl imidazolium ion, 1-sec-butyl-3-methyl imidazolium ion, 1-isobutyl-3-methyl imidazolium ion, 1-tert-butyl-3-methyl imidazolium ion, 1-methyl-3-pentyl imidazolium ion, 1-methyl-3-neopentyl imidazolium ion, 1-methyl-3-isopentyl imidazolium ion, 1-(2-methyl butyl)-3-methyl imidazolium ion, 1-methyl-3-tert-pentyl imidazolium ion, 1-hexyl-3-methyl imidazolium ion, 1-heptyl-3-methyl imidazolium ion, 1-methyl-3-octyl imidazolium ion, 1-methyl-3-phenyl imidazolium ion, 1-benzyl-3-methyl imidazolium ion, 1,3-diethyl imidazolium ion, 1-ethyl-3-propyl imidazolium ion, 1-ethyl-3-isopropyl imidazolium ion, 1-butyl-3-ethyl imidazolium ion, 1-sec-butyl-3-ethyl imidazolium ion, 1-isobutyl-3-ethyl imidazolium ion, 1-tert-butyl-3-ethyl imidazolium ion, 1-ethyl-3-pentyl imidazolium ion, 1-ethyl-3-neopentyl imidazolium ion, 1-ethyl-3-isopentyl imidazolium ion, 1-(2-methyl butyl)-3-ethyl imidazolium ion, 1-ethyl-3-tert-pentyl imidazolium ion, 1-ethyl-3-hexyl imidazolium ion, 1-ethyl-3-heptyl imidazolium ion, 1-ethyl-3-octyl imidazolium ion, 1,3-di-propyl imidazolium ion, 1-propyl-3-isoproyl imidazolium ion, 1-butyl-3-propyl imidazolium ion, 1-sec-butyl-3-propyl imidazolium ion, 1-isobutyl-3-propyl imidazolium ion, 1-tert-butyl-3-propyl imidazolium ion, 1-pentyl-3-propyl imidazolium ion, 1-neopentyl-3-propyl imidazolium ion, 1-isopentyl-3-propyl imidazolium ion, 1-(2-methyl butyl)-3-propyl imidazolium ion, 1-tert-pentyl-3-propyl imidazolium ion, 1,3-diisopropyl imidazolium ion, 1-butyl-3-propyl imidazolium ion, 1-sec-butyl-3-isopropyl imidazolium ion, 1-isobutyl-3-isopropyl imidazolium ion, 1-tert-butyl-3-isopropyl imidazolium ion, 1-pentyl-3-isopropyl imidazolium ion, 1-neopentyl-3-isopropyl imidazolium ion, 1-isopentyl-3-isopropyl imidazolium ion, 1-(2-methyl butyl)-3-isopropyl imidazolium ion, 1-tert-pentyl-isopropyl imidazolium ion, 1,3-dibutyl imidazolium ion, 1-butyl-3-isobutyl imidazolium ion, 1-butyl-3-sec-butyl imidazolium ion, 1-butyl-3-tert-butyl imidazolium ion, 1,3-diisobutyl imidazolium ion, 1-isobutyl-3-sec-butyl imidazolium ion, 1-isobutyl-3-tert-butyl imidazolium ion, 1,3-di-sec-butyl imidazolium ion, and 1-sec-butyl-3-tert-butyl imidazolium ion.

(2) Examples of a cation of which R₅, R₆, R₇ and R₈ are alkyl groups with 8 or less carbon atoms include 1,2,3-trimethyl imidazolium ion, 3-ethyl-1,2-dimethyl imidazolium ion, 1,2-dimethyl-3-propyl imidazolium ion, 1,2-dimethyl-3-isopropyl imidazolium ion, 2-ethyl-1,3-dimethyl imidazolium ion, 2-ethyl-1-methyl-3-propyl imidazolium ion, 2-ethyl-1-methyl-3-isopropyl imidazolium ion, 1-ethyl-3,4-dimethyl imidazolium ion, and 1,3-diethyl-4-methyl imidazolium ion.

(3) Examples of a cation of which R₅ and R₇ are alkyl groups with 8 or less carbon atoms, and of which R₆ and R₈ are substituents containing carbon, hydrogen and oxygen with 8 or less carbon atoms include 2-(2-methoxy ethyl)-1-ethyl-3-methyl imidazolium ion, 2-(2-methoxy ethyl)-1,3-dimethyl imidazolium ion, and 2-(2-methoxy ethyl)-1,3-diethyl imidazolium ion.

(4) Examples of a cation of which R₅ and R₇ are substituents containing carbon, hydrogen and oxygen with 8 or less carbon atoms, and of which R₆ and R₈ are hydrogen include 1-(2-methoxy ethyl)-3-methyl imidazolium ion, 1,3-di(2-methoxy ethyl)imidazolium ion, and 1-(2-ethoxy ethyl)-3-methyl imidazolium ion.

(5) Examples of a cation of which R₅ and R₇ are substituents containing carbon, hydrogen and oxygen with 8 or less carbon atoms, and of which R₆ and R₈ are alkyl groups with 8 or less carbon atoms include 1-(2-methoxy ethyl)-2,3-dimethyl imidazolium ion, 1,3-di(2-methoxy ethyl)-2-methyl imidazolium ion, and 1-(2-ethoxy ethyl)-2,3-dimethyl imidazolium ion.

(6) Examples of a cation of which R₅, R₆, R₇, and R₈ are substituents containing carbon, hydrogen and oxygen with 8 or less carbon atoms include 1,2-di(2-methoxy ethyl)-3-methyl imidazolium ion, and 1,2-di(2-methoxy ethyl)-3-ethyl imidazolium ion.

Among them, 1-ethyl-3-methyl imidazolium ion, 1-ethyl-2,3-dimethyl imidazolium ion, 1-ethyl-3,4-dimethyl imidazolium ion, and 1-(2-methoxy ethyl)-3-methyl imidazolium ion are particularly preferred.

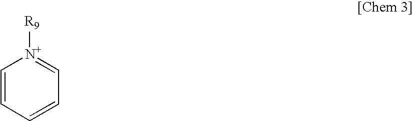

R₉ for composing the cation shown in the above formula 3 is preferably an alkyl group. Among substituents containing carbon, hydrogen and oxygen, an alkyl group is preferred. The number of carbon atoms is limited to 8 or less because, if exceeding 8, viscosity of the molten salt is increased, and ion diffusion performance of the electrolyte may be lowered. A more preferred range of the number of carbon atoms is 1 to 4.

Specific examples of the cation represented by the formula 3 will be given below.

(1) Examples of a cation of which R₉ is an alkyl group with 8 or less carbon atoms include N-methyl pyridinium ion, N-ethyl pyridinium ion, N-propyl pyridinium ion, N-isoproyl pyridinium ion, N-butyl pyridinium ion, N-isobutyl pyridinium ion, N-sec-butyl pyridinium ion, N-tert-butyl pyridinium ion, N-pentyl pyridinium ion, N-neopentyl pyridinium ion, N-isopentyl pyridinium ion, N-(2-methyl butyl) pyridinium ion, N-tert-pentyl pyridinium ion, N-hexyl pyridinium ion, N-heptyl pyridinium ion, and N-octyl pyridinium ion.

(2) Examples of a cation of which R₉ is a substituent containing carbon, hydrogen and oxygen with 8 or less carbon atoms include N-(2-methoxy ethyl) pyridinium ion, and N-(2-ethoxy ethyl) pyridinium ion.

Among them, N-butyl pyridinium ion is particularly preferred.

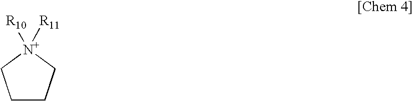

R₁₀ and R₁₁ for composing the cation shown in the above formula 4 may be either same or mutually different, including an alkyl group, a phenyl group, a benzyl group, or a substituent containing C, H and O. In particular, an alkyl group, a phenyl group, and a benzyl group are preferred. Among substituents containing carbon, hydrogen and oxygen, an alkyl group is preferred. The number of carbon atoms is limited to 8 or less because, if exceeding 8, viscosity of the molten salt is increased, and ion diffusion performance of the electrolyte may be lowered. A more preferred range of the number of carbon atoms is 1 to 4.

Specific examples of the cation shown in the formula 4 will be given below.

(1) Examples of a cation of which R₁₀ and R₁₁ are alkyl groups with 8 or less carbon atoms include N,N-dimethyl pyrrolidinium ion, N-ethyl-N-methyl pyrrolidinium ion, N-methyl-N-propyl pyrrolidinium ion, N-methyl-N-isopropyl pyrrolidinium ion, N-butyl-N-methyl pyrrolidinium ion, N-isobutyl-N-methyl pyrrolidinium ion, N-sec-butyl-N-methyl pyrrolidinium ion, N-tert-butyl-N-methyl pyrrolidinium ion, N-methyl-N-pentyl pyrrolidinium ion, N-hexyl-N-methyl pyrrolidinium ion, N-heptyl-N-methyl pyrrolidinium ion, N-methyl-N-octyl pyrrolidinium ion, N,N-diethyl pyrrolidinium ion, N-ethyl-N-propyl pyrrolidinium ion, N-ethyl-N-isopropyl pyrrolidinium ion, N-butyl-N-ethyl pyrrolidinium ion, N-isobutyl-N-ethyl pyrrolidinium ion, N-sec-butyl-N-ethyl pyrrolidinium ion, N-tert-butyl-N-ethyl pyrrolidinium ion, N-ethyl-N-pentyl pyrrolidinium ion, N-ethyl-N-hexyl pyrrolidinium ion, N-ethyl-N-heptyl pyrrolidinium ion, N-ethyl-N-octyl pyrrolidinium ion, N-(2-methoxy ethyl)-N-methyl pyrrolidinium ion, N-(2-ethoxy ethyl)-N-methyl pyrrolidinium ion, N-(2-propoxy ethyl)-N-methyl pyrrolidinium ion, and N-(2-isopropoxy ethyl)-N-methyl pyrrolidinium ion.

(2) Examples of a cation of which R₁₀ and R₁₁ are phenyl groups with 8 or less carbon atoms include N-methyl-N-phenyl pyrrolidinium ion, N-ethyl-N-phenyl pyrrolidinium ion, N-phenyl-N-propyl pyrrolidinium ion, N-phenyl-N-isopropyl pyrrolidinium ion, N-butyl-N-phenyl pyrrolidinium ion, N-pentyl-N-phenyl pyrrolidinium ion, N-hexyl-N-phenyl pyrrolidinium ion, N-heptyl-N-phenyl pyrrolidinium ion, N-octyl-N-phenyl pyrrolidinium ion, N-methyl-N-tolyl pyrrolidinium ion, N-ethyl-N-tolyl pyrrolidinium ion, N-propyl-N-tolyl pyrrolidinium ion, N-isopropyl-N-tolyl-pyrrolidinium ion, N-butyl-N-tolyl pyrrolidinium ion, N-pentyl-N-tolyl pyrrolidinium ion, N-hexyl-N-tolyl pyrrolidinium ion, N-heptyl-N-tolyl pyrrolidinium ion, and N-octyl-N-tolyl pyrrolidinium ion.

(3) Examples of a cation of which R₁₀ and R₁₁ are benzyl groups with 8 or less carbon atoms include N-benzyl-N-methyl pyrrolidinium ion, N-benzyl-N-ethyl pyrrolidinium ion, N-benzyl-N-propyl pyrrolidinium ion, N-benzyl-N-isopropyl pyrrolidinium ion, N-benzyl-N-butyl pyrrolidinium ion, N-benzyl-N-pentyl pyrrolidinium ion, N-benzyl-N-hexyl pyrrolidinium ion, N-benzyl-N-heptyl pyrrolidinium ion, N-benzyl-N-octyl pyrrolidinium ion, N-methyl-N-tolyl pyrrolidinium ion, N-ethyl-N-tolyl pyrrolidinium ion, N-propyl-N-tolyl pyrrolidinium ion, N-isopropyl-N-tolyl pyrrolidinium ion, N-butyl-N-tolyl pyrrolidinium ion, N-pentyl-N-tolyl pyrrolidinium ion, N-hexyl-N-tolyl pyrrolidinium ion, N-heptyl-N-tolyl pyrrolidinium ion, and N-octyl-N-tolyl pyrrolidinium ion.

(4) Examples of a cation of which R₁₀ and R₁₁ are substituents containing carbon, hydrogen and oxygen with 8 or less carbon atoms include N-(2-methoxy ethyl)-N-methyl pyrrolidinium ion, N-(2-methoxy ethyl)-N-ethyl pyrrolidinium ion, N-(2-ethoxy ethyl)-N-methyl pyrrolidinium ion, N-methyl-N-(2-methoxy phenyl) pyrrolidinium ion, N-methyl-N-(4-methoxy phenyl) pyrrolidinium ion, N-ethyl-N-(2-methoxy phenyl) pyrrolidinium ion, and N-ethyl-N-(4-methoxy phenyl) pyrrolidinium ion.

Among them, N-methyl-N-propyl pyrrolidinium ion, N-methyl-N-isopropyl pyrrolidinium ion, N-butyl-N-methyl pyrrolidinium ion, N-isobutyl-N-methyl pyrrolidinium ion, N-sec-butyl-N-methyl pyrrolidinium ion, N-(2-methoxy ethyl)-N-methyl pyrrolidinium ion, and N-(2-ethoxy ethyl)-N-methyl pyrrolidinium ion are particularly preferred.

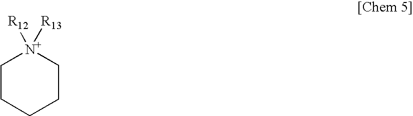

R₁₂ and R₁₃ for composing the cation shown in the above formula 5 may be either same or mutually different, including an alkyl group, a phenyl group, a benzyl group, or a substituent containing C, H and O. In particular, an alkyl group, a phenyl group, and a benzyl group are preferred. Among substituents containing carbon, hydrogen and oxygen, an alkyl group is preferred. The number of carbon atoms is limited to 8 or less because, if exceeding 8, viscosity of the molten salt is increased, and ion diffusion performance of the electrolyte may be lowered. A more preferred range of the number of carbon atoms is 1 to 4.

Specific examples of the cation shown in the formula 5 will be given below.

(1) Examples of a cation of which R₁₂ and R₁₃ are alkyl groups with 8 or less carbon atoms include N,N-dimethyl piperidinium ion, N-ethyl-N-methyl piperidinium ion, N-methyl-N-propyl piperidinium ion, N-methyl-N-isopropyl piperidinium ion, N-butyl-N-methyl piperidinium ion, N-isobutyl-N-methyl piperidinium ion, N-sec-butyl-N-methyl piperidinium ion, N-tert-butyl-N-methyl piperidinium ion, N-methyl-N-pentyl piperidinium ion, N-hexyl-N-methyl piperidinium ion, N-heptyl-N-methyl piperidinium ion, N-methyl-N-octyl piperidinium ion, N,N-diethyl piperidinium ion, N-ethyl-N-propyl piperidinium ion, N-ethyl-N-isopropyl piperidinium ion, N-butyl-N-ethyl piperidinium ion, N-isobutyl-N-ethyl piperidinium ion, N-sec-butyl-N-ethyl piperidinium ion, N-tert-butyl-N-ethyl piperidinium ion, N-ethyl-N-pentyl piperidinium ion, N-ethyl-N-hexyl piperidinium ion, N-ethyl-N-heptyl piperidinium ion, N-ethyl-N-octyl piperidinium ion, N-(2-methoxy ethyl)-N-methyl piperidinium ion, N-(2-ethoxy ethyl)-N-methyl piperidinium ion, N-(2-propoxy ethyl)-N-methyl piperidinium ion, and N-(2-isopropoxy ethyl)-N-methyl piperidinium ion.

(2) Examples of a cation of which R₁₂ and R₁₃ are phenyl groups with 8 or less carbon atoms include N-methyl-N-phenyl piperidinium ion, N-ethyl-N-phenyl piperidinium ion, N-phenyl-N-propyl piperidinium ion, N-phenyl-N-isopropyl piperidinium ion, N-butyl-N-phenyl piperidinium ion, N-pentyl-N-phenyl piperidinium ion, N-hexyl-N-phenyl piperidinium ion, N-heptyl-N-phenyl piperidinium ion, N-octyl-N-phenyl piperidinium ion, N-methyl-N-tolyl piperidinium ion, N-ethyl-N-tolyl piperidinium ion, N-propyl-N-tolyl piperidinium ion, N-isopropyl-N-tolyl piperidinium ion, N-butyl-N-tolyl piperidinium ion, N-pentyl-N-tolyl piperidinium ion, N-hexyl-N-tolyl piperidinium ion, N-heptyl-N-tolyl piperidinium ion, and N-octyl-N-tolyl piperidinium ion.

(3) Examples of a cation of which R₁₂ and R₁₃ are benzyl groups with 8 or less carbon atoms include N-benzyl-N-methyl piperidinium ion, N-benzyl-N-ethyl piperidinium ion, N-benzyl-N-propyl piperidinium ion, N-benzyl-N-isopropyl piperidinium ion, N-benzyl-N-butyl piperidinium ion, N-benzyl-N-pentyl piperidinium ion, N-benzyl-N-hexyl piperidinium ion, N-benzyl-N-heptyl piperidinium ion, N-benzyl-N-octyl piperidinium ion, N-methyl-N-tolyl piperidinium ion, N-ethyl-N-tolyl piperidinium ion, N-propyl-N-tolyl piperidinium ion, N-isopropyl-N-tolyl-piperidinium ion, N-butyl-N-tolyl piperidinium ion, N-pentyl-N-tolyl piperidinium ion, N-hexyl-N-tolyl piperidinium ion, N-heptyl-N-tolyl piperidinium ion, and N-octyl-N-tolyl piperidinium ion.

(4) Examples of a cation of which R₁₂ and R₁₃ are substituents containing carbon, hydrogen and oxygen with 8 or less carbon atoms include N-(2-methoxy ethyl)-N-methyl piperidinium ion, N-(2-methoxy ethyl)-N-ethyl piperidinium ion, N-(2-ethoxy ethyl)-N-methyl piperidinium ion, N-methyl-N-(2-methoxy phenyl) piperidinium ion, N-methyl-N-(4-methoxy phenyl) piperidinium ion, N-ethyl-N-(2-methoxy phenyl) piperidinium ion, and N-ethyl-N-(4-methoxy phenyl) piperidinium ion.

Among them, N-methyl-N-propyl piperidinium ion, N-methyl-N-isopropyl piperidinium ion, N-butyl-N-methyl piperidinium ion, N-isobutyl-N-methyl piperidinium ion, N-sec-butyl-N-methyl piperidinium ion, N-(2-methoxy ethyl)-N-methyl piperidinium ion, and N-(2-ethoxy ethyl)-N-methyl piperidinium ion are particularly preferred.

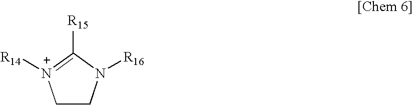

R₁₄, R₁₅, and R₁₆ shown in the above formula 6 may be either same or mutually different, including an alkyl group, or a substituent containing C, H and O. In particular, an alkyl group is preferred. Among substituents containing carbon, hydrogen and oxygen, an alkyl group is preferred. The number of carbon atoms is limited to 8 or less because, if exceeding 8, viscosity of the molten salt is increased, and ion diffusion performance of the electrolyte is lowered. A more preferred range of the number of carbon atoms is 1 to 4 in R₁₄ and R₁₆, and 1 to 2 in R₁₅.

Specific examples of the cation shown in the formula 6 will be given below.

(1) Examples of a cation of which R₁₄, R₁₅, and R₁₆ are alkyl groups with 8 or less carbon atoms include 1,2,3-trimethyl imidazolinium ion, 3-ethyl-1,2-dimethyl imidazolinium ion, 1,2-dimethyl-3-propyl imidazolinium ion, 1,2-dimethyl-3-isopropyl imidazolinium ion, 2-ethyl-1,3-dimethyl imidazolinium ion, 2-ethyl-1-methyl-3-propyl imidazolinium ion, and 2-ethyl-1-methyl-3-isopropyl imidazolinium ion.

(2) Examples of a cation of which R₁₄ and R₁₆ are substituents containing carbon, hydrogen and oxygen with 8 or less carbon atoms, and of R₁₅ is an alkyl group with 8 or less carbon atoms include 1-(2-methoxy ethyl)-2,3-dimethyl imidazolinium ion, 1,3-di(2-methoxy ethyl)-2-methyl imidazolinium ion, and 1-(2-ethoxy ethyl)-2,3-dimethyl imidazolinium ion.

Among them, 3-ethyl-1,2-dimethyl imidazolinium ion is particularly preferred.

The anion component for composing the molten salt is not particularly limited, but it is preferred to contain at least one of BF₄⁻, PF₆⁻, B(C₂O₄)₂⁻, and anions shown in the following chemical formulas A to D.
(CₘF₂ₘ₊₁SO₃)⁻ (Chemical formula A)
where m is 1 or more and 8 or less.
(CₙF₂ₙ₊₁SO₂)(CₚF₂ₚ₊₁SO₂)N⁻ (Chemical formula B)
where n and p each are 1 or more and 8 or less, either same or mutually different.
(C_{q}F_{2q+1}SO₂)(CN)N⁻ (Chemical formula C)
N⁻(CN)₂ (Chemical formula D)
where q is 1 or more and 8 or less. In the chemical formulas A to C, the values of m, n, p and q are 8 or less because, if these values exceed 8, viscosity of the molten salt is increased, and ion diffusion performance of the electrolyte may be lowered.

In particular, it is desired that a fluorine atom is present in the substituent. As a result, viscosity of the molten salt is decreased, and ion diffusion performance of the electrolyte is improved, so that luminous intensity may be enhanced. Especially, (CF₃SO₂)₂N⁻ is preferred.

In order to obtain a sufficient life by addition of the molten salt, the content of the molten salt in the electrolyte is preferred to be 80% or more by volume. A more preferred range is 90% or more by volume.

A nonionic organic solvent may be also added to the electrolyte. By adding such an organic solvent, the viscosity is lowered, and the luminous intensity is further improved. As the organic solvent, the same organic solvent as used in a lithium secondary battery can be used, and a usable solvent can be selected from the group consisting of ester carbonates such as propylene carbonate, ethylene carbonate, vinylene carbonate, and methyl propyl carbonate; esters such as ethyl propionate, γ-butyrolactone, γ-valerolactone, and δ-valerolactone; ethers such as ethylene glycol dimethyl ether, and ethylene glycol diethyl ether; and various solvents prepared by adding a substituent such as fluorine to these compounds. The organic solvent may either one type or two or more types, and among them, propylene carbonate, ethylene carbonate, and vinylene carbonate are particularly preferred.

However, excessive addition of the organic solvent may spoil the reversibility of the oxidation-reduction reaction, and therefore, the content of the organic solvent is preferred to be 20 vol. % or less of the electrolyte.

By using flat electrodes as the first and second electrodes, the first electrode and second electrode may be set opposite to each other and set apart from each other by a spacer, and the electrolyte may be contained in the space formed by the first and second electrodes and the spacer, and sealed by a sealing member such as epoxy resin. Alternatively, a cell comprising the first and second electrodes, the porous layer and the electrolyte may be packed in a film container. As a result, since the sealing member is not needed, dissolving of the sealing member into the electrolyte to impede illumination of the dye can be avoided. At the same time, the manufacturing process can be simplified.

In the light-emitting device, at least one of the first and second electrodes is a transparent electrode for picking up light. The surface of the transparent electrode opposite to the surface electrically contacting with the electrolyte functions as a light-emitting surface (light pickup surface). Hence, the side of the film container opposite to the light-emitting surface is desirably formed of a transparent thermoplastic resin, and other positions than this surface are preferably formed of a laminate film containing an Al layer or Al alloy layer in order to suppress inactivation of the dye due to transmission of oxygen.

The transparent thermoplastic resin is not particularly limited, but, for example, polyolefin such as polyethylene or polypropylene may be used.

The laminate film containing an Al layer or Al alloy layer is not particularly limited, but an example is a laminate film comprising: a thermoplastic resin layer composing the inside of a container; a resin layer composing the outside of the container; and an Al layer or Al alloy layer arranged the thermoplastic resin layer and the resin layer.

The thermoplastic resin layer is not particularly specified as far as it functions as a sealant layer for sealing the container, but it may be formed of, for example, polyolefin such as polyethylene (PE) or polypropylene (PP).

The resin layer is intended to reinforce the Al layer and Al alloy layer, and may be formed of a polymer such as polypropylene, polyethylene, nylon, or polyethylene terephthalate (PET).

The thickness of the film composing the film container is preferably 0.5 mm or less, and more preferably 0.2 mm or less. As a result, the light-emitting device cell is reduced in thickness. To assure the mechanical strength of the container, the lower limit of the film thickness is preferably 0.01 mm.

The luminous dye in the light-emitting device reacts by oxidation and reduction with a first electrode and a second electrode by a voltage applied from outside, and becomes oxide and reduced form. In the case of Ru bipyridyl complex, the difference between the potential for reducing divalent Ru into monovalent one and the potential for oxidizing divalent Ru into trivalent one is about 2.2V in organic solvent such as acetonitrile. This potential difference is decreased to 1.3V in molten salt (ionic liquid). This is because the reducing potential from divalent to monovalent form is shifted to the positive potential although the oxidizing potential from divalent to trivalent form is hardly changed.

A porous layer formed of n-type semiconductor is an electrode capable of injecting electrons efficiently into dye. Titania is desired as n-type semiconductor. When using organic solvent such as acetonitrile in electrolyte, the reducing potential of luminous dye containing Ru is at negative potential side from conduction band of n-type semiconductor. Accordingly, to reduce the luminous dye, it is required to shift the potential of the n-type semiconductor electrode further to negative potential side by injecting electrons in the porous layer formed of n-type semiconductor. As a result, the driving voltage is increased.

When molten salt (ionic liquid) is used in the electrolyte as in this example, injection of electrons in porous layer is not needed because the reducing potential of luminous dye containing Ru is shifted to positive potential. As a result, the required voltage depends on the oxidizing potential, and thus low voltage driving is possible. The luminous dye of the example can control the emission start voltage at 1.5V or more to 2.0V or less. Emission start voltage is the voltage applied when minimum unit of 1 cd/m² is provided by a luminance meter BM-8 (manufactured by Topcon) or a luminous meter having a similar function.

When applying voltage to the luminous dye in which an ITO electrode is used as first electrode and second electrode, the potential for applying this voltage cannot be set constantly. Hence, in this luminous dye, the potential is deviated during driving, and thus the required oxide and reduced form may not be obtained. As a result, the molten salt is likely to decompose and the life is shortened. As in this example, by using porous layer formed of n-type semiconductor, the potential can be set constant when applying voltage, and decomposition reaction of molten salt by changes in absolute potential can be prevented. Hence, the life of the light-emitting device can be extended.

A second light-emitting device will be explained.

The second light-emitting device is a light-emitting device comprising: a first electrode; a porous layer arranged on the first electrode; a second electrode opposite to the porous layer; and an electrolyte layer which electrically contacts with the first electrode and the second electrode, and contains a luminous dye. Either the first electrode or the second electrode is formed of a metal-containing substrate. Examples of the metal-containing substrate include a metal substrate and an alloy substrate.

The metal is not particularly limited, but includes gold, silver, copper, aluminum, nickel, iron, and others. The alloy contains at least one metal selected from the group consisting of gold, silver, copper, aluminum, nickel, and iron. In particular, nickel and nickel alloy are preferred. As a result, the luminous intensity can be further enhanced.

The thicknesses of the metal substrate and the alloy substrate each are preferably 0.02 mm to 10 mm. The reason is as follows. If the thickness is less than 0.02 mm, the mechanical strength of the light-emitting device may be lowered. If the thickness exceeds 10 mm, it is hard to reduce the thickness of the light-emitting device. A more preferred range of the thickness is 0.2 mm to 2 mm.

Either one of the first electrode and the second electrode is formed of metal or alloy. The other is preferably a transparent electrode in order to assure the light-emitting surface (light pickup surface). The transparent electrode may be same as explained in the first light-emitting device. In order to lower the resistance of the transparent electrode, it is desired to insert metal as wiring.

Since the luminous intensity from the porous layer is relatively higher than the luminous intensity from the second electrode, it is preferred to form the second electrode from a transparent electrode to function as the light-emitting surface.

The porous layer may be made of the same material as explained in the first light-emitting device. When the porous layer is made of metal, the same material as the metal substrate can be used. The porous layer can be also formed by making the surface of the metal substrate porous by anodic oxidation.

The electrolyte may be made of the same material as explained in the first light-emitting device. Instead, it may be formed of a material obtained by dissolving a dye in an organic solvent, or of a material containing other molten salt and dye than those explained in the first light-emitting device.

The first and second light-emitting devices can emit light whether direct current or alternating current is applied. However, when using the electrolyte containing the molten salt having a cation component of the structure represented by the above formula (A), it is preferred to apply alternating current. As a result, occasions of collision of an oxidized substance and a reduced substance are increased, so that the luminous intensity can be enhanced.

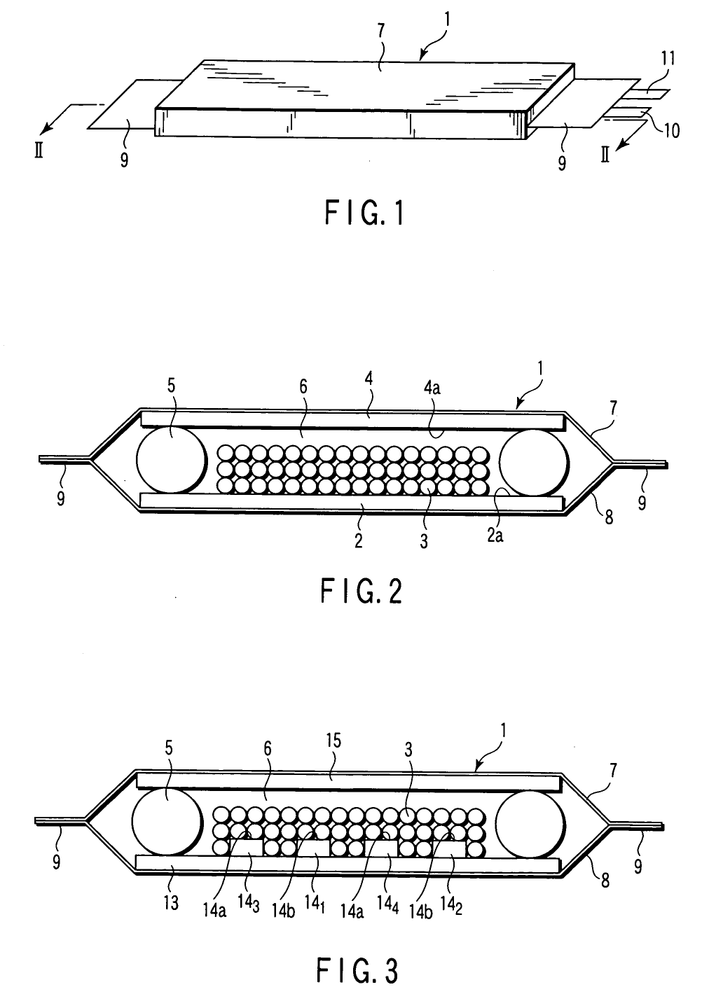

The first and second light-emitting devices will be explained below by referring to FIGS. 1 to 5.

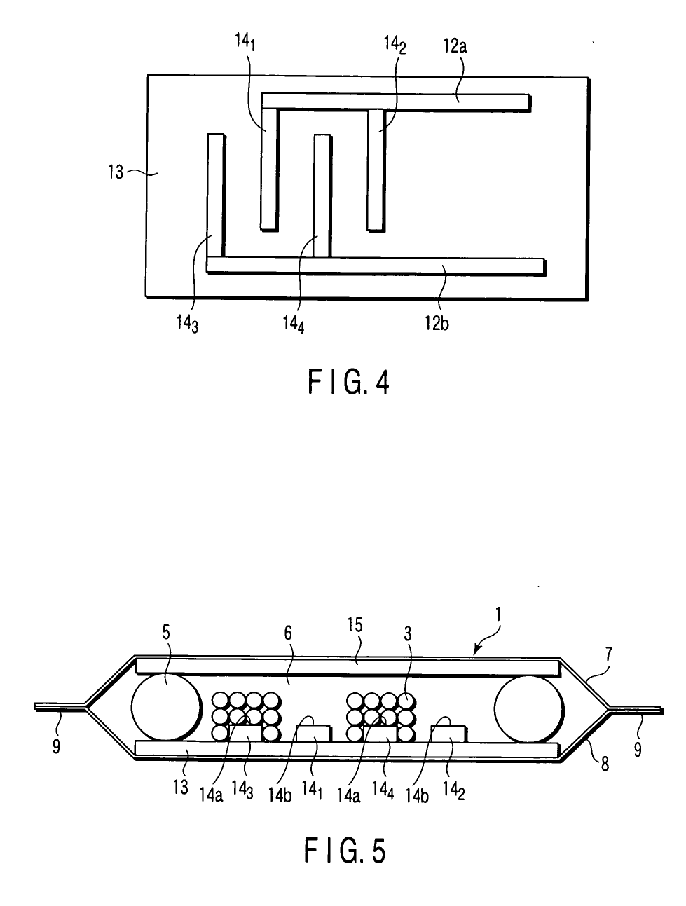

FIG. 1 is a schematic perspective view showing first and second light-emitting devices according to an embodiment of the invention. FIG. 2 is a sectional view taken along line II-II of the light-emitting device in FIG. 1. FIG. 3 is a schematic sectional view showing the light-emitting device according to another embodiment of the invention. FIG. 4 is a schematic plan view showing a comb-shaped electrode assembled in the light-emitting device in FIG. 3. FIG. 5 is a schematic sectional view showing the light-emitting device according to still another embodiment of the invention.

As shown in FIG. 1, a light-emitting device cell is contained in a film container 1. The light-emitting device cell comprises: a first electrode 2 of flat plate type; a porous layer 3 formed on the first electrode 2; a second electrode 4 of flat plate type; an insulating spacer 5 of rectangular frame shape arranged between the peripheral edge of the first electrode 2 and the peripheral edge of the second electrode 4; and an electrolyte 6.

The first electrode 2 has a first surface 2a. The second electrode 4 has a second surface 4a. The porous layer 3 is provided on the first surface 2a of the first electrode 2. The porous layer 3 faces the second surface 4a of the second electrode 4.

The porous layer 3 is composed of an assembly of particles of a conductor, semiconductor or insulator. The electrolyte 6 is contained in a space enclosed by the first electrode 2, the second electrode 4 and the spacer 5, and the majority is held on the porous layer 3. Thus, by interposing the electrolyte 6 between the first surface 2a of the first electrode 2 and the second surface 4a of the second electrode 4, it is possible to bring the electrolyte 6 into electrical contact with both the first electrode 2 and the second electrode 4.

In order to ensure a light pickup surface (light-emitting surface), at least one of the first electrode 2 and the second electrode 4 is a transparent electrode. In FIG. 2, for example, the second electrode 4 is a transparent electrode. The film container 1 is formed of a thermoplastic resin film 7 which is transparent at the surface facing the second electrode 4, and the opposite side is formed of a laminate film 8 containing an Al layer or Al alloy layer. Both ends 9 of the transparent thermoplastic resin film 7 and the laminate film 8 are sealed by heat sealing.

A lead 10 for the first electrode has one end connected electrically to the first electrode 2, and the other end drawn out from the heat seal 9 of the film container 1. On the other hand, a lead 11 for the second electrode has one end connected electrically to the second electrode 4, and the other end drawn out from the heat seal 9 of the film container 1.

In FIGS. 1 and 2, the first electrode and the second electrode are arranged opposite each other across a certain distance, but the first electrode and the second electrode may be also arranged on the same insulating substrate. Such an example is shown in FIGS. 3 to 5. In FIGS. 3 to 5, the same members as explained in FIG. 1 are identified with the same reference numerals, and explanation thereof is omitted.

A pair of comb-shaped electrodes 12a, 12b are arranged on an insulating support substrate 13. The comb-shaped electrode 12a as the second electrode has two band electrodes 14₁, 14₂ arranged across an interval. The two band electrodes 14₁, 14₂ have a second surface 14b. The comb-shaped electrode 12b as the first electrode has two band electrodes 14₃, 14₄ arranged across an interval. The two band electrodes 14₃, 14₄ has a first surface 14a. The comb-shaped electrodes 12a, 12b are engaged with each other, having mutual band electrodes facing each other, such that the band electrode of one comb-shaped electrode may be positioned next to the band electrode of the other comb-shaped electrode.

In the light-emitting device in FIG. 3, porous layers 3 are formed on the second surface 14b of the band electrodes 14₁ to 14₂ and the first surface 14a of the band electrodes 14₃ to 14₄, and interposed between the second surface 14b and the first surface 14a. Therefore, it corresponds to the embodiment in which porous layers are formed in both the first surface of the first electrode and the second surface of second electrode. The light-emitting device of such a configuration is advantageous in alternating current driving. The insulating substrate 15 faces the surface on which the porous layer 3 of the support substrate 13 is formed. The support substrate 13 and insulating substrate 15 may be made of, for example, transparent substrates small in absorption in visible region such as a glass substrate or a plastic substrate. The comb-shaped electrodes 12a, 12b may be made of the transparent conductive film, metal substrate, or alloy substrate as mentioned above.

The electrolyte 6 is contained in a space enclosed by the support substrate 13, the insulating substrate 15 and the spacer 5, and the majority is held on the porous layer 3. Thus, by interposing the electrolyte 6 between the first surface 14a of the first electrode 12b and the second surface 14b of the second electrode 12a, it is possible to bring the electrolyte 6 into electrical contact with both the first electrode 12b and the second electrode 12a.

In the light-emitting device shown in FIG. 5, on the other hand, the porous layers 3 are formed only on the first surface 14a of the band electrodes 143, 144 of the comb-shaped electrode 12b serving as the first electrode.

The electrolyte 6 is contained in a space enclosed by the support substrate 13, the insulating substrate 15 and the spacer 5, and is held on the porous layer 3. Thus, by interposing the electrolyte 6 between the first surface 14a of the first electrode 12b and the second surface 14b of the second electrode 12a, it is possible to bring the electrolyte 6 into electrical contact with both the first electrode 12b and the second electrode 12a.

The light-emitting device of such a configuration is advantageous in direct current driving. In direct current driving, it may fail to emit light if the porous layer 3 is present on the second surface 14b of the comb-shaped electrode 12a serving as the second electrode 4.

Specific examples will be explained below by referring to the drawings.

### EXAMPLE 1

<Fabrication of First Electrode and Porous Layer>

On a glass substrate of 1000 μm in thickness, a fluorine-doped tin oxide thin film of about 1 μm in thickness (sheet resistance of 6Ω/sq) was formed, and a transparent electrode was prepared. On the fluorine-doped tin oxide thin film of the transparent electrode, Nanoxide D, titania paste manufactured by Solaronix in Switzerland, was applied in a gap of 50 microns. The resultant was then dried and baked for 30 minutes at 450° C., and this process was repeated four times to obtain a porous titania film of 20 microns in thickness as a porous layer.

<Fabrication of Second Electrode>

On a glass substrate, a fluorine-doped tin oxide thin film (sheet resistance of 6Ω/sq) was formed, and a counter electrode (second electrode) was prepared.

The fluorine-doped tin oxide thin film of the second electrode was set opposite to the surface of the porous layer side of the first electrode, and ionomer resin Himilan 1702 (film thickness of about 50 μm) was interposed there between as a spacer, so that the first electrode and the second electrode were arranged opposite to each other across a gap of 50 microns. An electrolysis solution was injected into the gap between the first electrode and the second electrode. The electrolysis solution was prepared by dissolving 0.2 g of ruthenium (II) trisbipyridyl (PF₆⁻)₂ as a luminous dye in 1.1 g of 1-ethyl-3-methyl imidazolium bis(trifluoromethyl sulfonyl)imide as an ionic liquid. A cation component of the ionic liquid, 1-ethyl-3-methyl imidazolium ion, has the structure shown in the above formula 2. An anion component, a bis(trifluoromethyl sulfonyl)imide ion, has the structure shown in the above chemical formula B.

The injection port for the electrolysis solution was sealed with epoxy resin. Then, the first electrode was negative and the second electrode was positive, a voltage of 3V was applied, and a current was supplied. In this case, light was emitted in a quantity of 400 cd/m².

### EXAMPLE 2

A light-emitting device was fabricated in the same configuration as explained in Example 1, except that the electrolysis solution was prepared by dissolving 0.2 g of ruthenium (II) trisbipyridyl (PF₆⁻)₂ as a luminous dye in 1.1 g of 1-ethyl-3-methyl imidazolium PF₆, and the fabricated light-emitting device was evaluated in the same manner as in Example 1. Results are shown in Table 1.

### EXAMPLE 3

A light-emitting device was fabricated in the same configuration as explained in Example 1, except that the electrolysis solution was prepared by dissolving 0.2 g of ruthenium (II) trisbipyridyl (PF₆⁻)₂ as a luminous dye in 1.1 g of dimethyl ethyl butyl ammonium bis(trifluoromethyl sulfonyl)imide, and the fabricated light-emitting device was evaluated in the same manner as in Example 1. Results are shown in Table 1. Note that the dimethyl ethyl butyl ammonium ion as the cation component of the ionic liquid has the structure shown in the above formula 1.

### EXAMPLES 4 TO 10 AND COMPARATIVE EXAMPLE 11

Light-emitting devices were fabricated in the same configuration as explained in Example 1, except that the ionic liquid and luminous dye having the composition as shown in Table 1 were used, and the fabricated light-emitting devices were evaluated in the same manner as in Example 1. Results are shown in Table 1.

### EXAMPLE 12

A light-emitting device was fabricated in the same configuration as explained in Example 1, except that a porous titania film of P25 manufactured by Nippon Aerosil Co., Ltd., was used as a porous layer, and the fabricated light-emitting device was evaluated in the same manner as in Example 1. Results are shown in Table 2.

### COMPARATIVE EXAMPLE 13

A light-emitting device was fabricated in the same configuration as explained in Example 1, except that a porous film of SiO₂ (particle size of about 10 nm) was used as a porous layer, and the fabricated light-emitting device was evaluated in the same manner as in Example 1. Results are shown in Table 2.

### COMPARATIVE EXAMPLE 14

A light-emitting device was fabricated in the same configuration as explained in Example 1, except that an Al plate of 1 mm in thickness was used instead of the transparent electrode as the first electrode, and that a porous film of Al (particle size of about 10 nm) was used as a porous layer, and the fabricated light-emitting device was evaluated in the same manner as in Example 1. Results are shown in Table 2.

### COMPARATIVE EXAMPLE 15

A light-emitting device was fabricated in the same configuration as explained in Example 1, except that a Ni plate of 1 mm in thickness was used instead of the transparent electrode as the first electrode, and that a porous film of Al₂O₃ (particle size of about 10 nm) was used as a porous layer, and the fabricated light-emitting device was evaluated in the same manner as in Example 1. Results are shown in Table 2.

### COMPARATIVE EXAMPLE 1

A light-emitting device was fabricated in the same configuration as explained in Example 1, except that the electrolysis solution was prepared by dissolving 0.2 g of ruthenium (II) trisbipyridyl (PF₆⁻)₂ as a luminous dye in 1.1 g of acetonitrile, and the fabricated light-emitting device was evaluated in the same manner as in Example 1. Results are shown in Table 2.

In the obtained light-emitting devices of Examples 1 to 10, Example 12, and Comparative examples 1, 11, 13, 14 and 15, the half-life is measured by finding when the luminous intensity becomes ½ of the initial level by the following method, and results are shown in Tables 1 and 2, supposing the half-life of Comparative example 1 as 100.

Luminance was measured by BM-8 manufactured by Topcon. Luminance in a central part of the device and in a range of about 1 mm in diameter was used in measurement of half-life.

TABLE 1

| | | | | Luminous | |
|---|---|---|---|---|---|
| | Molten salt | Molten salt | | intensity | Half- |
| | Cation component | Anion component | Luminous dye | (cd/m²) | life |
| Example 1 | 1-ethyl-3-methyl | bis(trifluoromethyl | ruthenium (II) | 400 | 300 |
| | imidazolium | sulfonyl)imide | trisbipyridyl | | |
| | (Chem 2) | (Chemical Formula B) | (PF₆⁻)₂ | | |
| Example 2 | 1-ethyl-3-methyl | PF₆ | ruthenium (II) | 350 | 280 |
| | imidazolium | | trisbipyridyl | | |
| | (Chem 2) | | (PF₆⁻)₂ | | |
| Example 3 | dimethyl ethyl | bis(trifluoromethyl | ruthenium (II) | 420 | 250 |
| | butyl ammonium | sulfonyl)imide | trisbipyridyl | | |
| | (Chem 1) | (Chemical formula B) | (PF₆⁻)₂ | | |
| Example 4 | ethyl butyl | PF₆ | ruthenium (II) | 320 | 280 |
| | imidazolium | | trisbipyridyl | | |
| | | | (PF₆⁻)₂ | | |
| Example 5 | N-butyl-N-methyl | [N(CN)₂]⁻ | ruthenium (II) | 300 | 200 |
| | pyrrolidinium | | trisbipyridyl | | |
| | | | (PF₆⁻)₂ | | |
| Example 6 | N-methyl-N-propyl | bis(trifluoromethyl | ruthenium (II) | 280 | 260 |
| | piperidinium | sulfonyl)imide | trisbipyridyl | | |
| | | (Chemical formula B) | (PF₆⁻)₂ | | |
| Example 7 | 1-ethyl-3-methyl | [N(CN)₂]⁻ | ruthenium (II) | 380 | 200 |
| | imidazolium | | trisbipyridyl | | |
| | (Chem 2) | | (PF₆⁻)₂ | | |
| Example 8 | 1-ethyl-3-methyl | BF₄ | ruthenium (II) | 380 | 250 |
| | imidazolium | | trisbipyridyl | | |
| | (Chem 2) | | (PF₆⁻)₂ | | |
| Example 9 | N-butyl-N-methyl | BF₄ | ruthenium (II) | 340 | 200 |
| | pyrrolidinium | | trisbipyridyl | | |
| | (Chem 4) | | (PF₆⁻)₂ | | |
| Example 10 | N-methyl-N-propyl | BF₄ | ruthenium (II) | 330 | 200 |
| | piperidinium | | trisbipyridyl | | |
| | (Chem 5) | | (PF₆⁻)₂ | | |
| Comparative | 1-ethyl-3-methyl | bis(trifluoromethyl | tris(2-phenyl | 200 | 150 |
| example 11 | imidazolium | sulfonyl)imide | pyridine)iridium | | |
| | (Chem 2) | (Chemical formula B) | | | |

TABLE 2

| | | | | Luminous | |
|---|---|---|---|---|---|
| | Molten salt | Molten salt | | intensity | Half- |
| | Cation component | Anion component | Luminous dye | (cd/m²) | life |
| Example 12 | 1-ethyl-3-methyl | bis(trifluoromethyl | ruthenium (II) | 450 | 310 |
| | imidazolium | sulfonyl)imide | trisbipyridyl | | |
| | (Chem 2) | (Chemical formula B) | (PF₆⁻)₂ | | |
| Comparative | 1-ethyl-3-methyl | bis(trifluoromethyl | ruthenium (II) | 250 | 200 |
| example 13 | imidazolium | sulfonyl)imide | trisbipyridyl | | |
| | (Chem 2) | (Chemical formula B) | (PF₆⁻)₂ | | |
| Comparative | 1-ethyl-3-methyl | bis(trifluoromethyl | ruthenium (II) | 300 | 210 |
| example 14 | imidazolium | sulfonyl)imide | trisbipyridyl | | |
| | (Chem 2) | (Chemical formula B) | (PF₆⁻)₂ | | |
| Comparative | 1-ethyl-3-methyl | bis(trifluoromethyl | ruthenium (II) | 260 | 200 |
| example 15 | imidazolium | sulfonyl)imide | trisbipyridyl | | |
| | (Chem 2) | (Chemical formula B) | (PF₆⁻)₂ | | |
| Comparative | — | — | ruthenium (II) | 300 | 100 |
| example 1 | | | trisbipyridyl | | |
| | | | (PF₆⁻)₂ | | |

As clear from Tables 1 and 2, the light-emitting devices of Examples 1 to 10 and 12 each having an electrolyte containing a molten salt can be found to be longer in half-life as compared with the light-emitting device of Comparative example 1 using an organic solvent instead of the molten salt.

By comparison of Examples 1 to 10 and Comparative example 11, it is known that Examples 1 to 10 each using a luminous dye containing a complex having Ru in central metal are higher in luminous intensity and longer in half-life as compared with Comparative Example 11 containing a complex having Ir in central metal.

By comparison of Examples 8 to 10, it is understood that the composition shown in the formula 2 used in Example 8 is preferred as a cation component of a molten salt.

By comparison of Examples 1, 2, 7 and 8, it is understood that the composition shown in the chemical formula B used in Example 1 is preferred as an anion component of a molten salt.

By comparison of Examples 1 and 12, it is known that Example 12 using a porous film of TiO₂ particles that contains no acid component in tradename of P25 is preferred from the viewpoint of luminous intensity and half-life.

By comparison of Example 12 and Comparative Examples 13 to 15, it is known that Example 12 having a porous film made of TiO₂ particles is superior in both luminous intensity and half-life to Comparative Example 13 having a porous film made of SiO₂ particles, Comparative Example 14 having a porous film made of Al particles, or Comparative Example 15 having a porous film made of Al₂O₃ particles.

### EXAMPLE 16

A cell already packed with an electrolysis solution but not having an injection port sealed by epoxy resin was prepared as the cell of Example 1, the cell was covered with a polyethylene film of 0.2 mm in thickness in a glove box, and the opening was sealed by heat sealing at 200° C. The obtained light-emitting device and the cell of Example 1 having the injection port sealed by epoxy resin were heated for 500 hours in a thermostatic oven at 80° C., and the luminous intensity was measured. In this case, the luminous intensity of Example 1 was lowered to 150 cd/m², but was unchanged at 400 cd/m² in the cell of Example 16.

### EXAMPLE 17

A cell already packed with an electrolysis solution but not having an injection port sealed by epoxy resin was prepared as the cell of Example 1. The surface of the second electrode of the cell of Example 1 was covered with a polyethylene film of 0.2 mm in thickness in a glove box, and the surface of the first electrode was covered with a laminate film of 0.2 mm in thickness. The opening was sealed by heat-sealing at 200° C., and the light-emitting device in the structure show in FIGS. 1 and 2 was obtained. The laminate film used was a laminate film of a polyethylene film, an Al layer, and a PET film, and the first electrode was coated such that the polyethylene film was positioned at the inner side to function as a sealant layer. The obtained light-emitting device and the cell of Example 1 having the injection port sealed by epoxy resin were heated for 500 hours in a thermostatic oven at 80° C., and the luminous intensity was measured. In this case, the luminous intensity of Example 1 was lowered to 150 cd/m², but was unchanged at 400 cd/m² in the cell of Example 17.

### EXAMPLE 18

<Fabrication of First Electrode and Porous Layer>

On a glass substrate of 1000 μm in thickness, a fluorine-doped tin oxide thin film of about 1 μm in thickness (sheet resistance of 6Ω/sq) was formed, and a transparent electrode was prepared. On the fluorine-doped tin oxide thin film of the transparent electrode, Nanoxide D, titania paste manufactured by Solaronix in Switzerland, was applied in a gap of 50 microns. The resultant was then dried and baked for 30 minutes at 450° C., and the process was repeated four times to obtain a porous titania film of 20 microns in thickness as a porous layer.

<Fabrication of Second Electrode>

A nickel plate of 1 mm in thickness was prepared as a counter electrode (second electrode).

The second electrode was set opposite to the porous layer side of the first electrode, and ionomer resin Himilan 1702 (film thickness of about 50 μm) was interposed therebetween as a spacer, so that the first electrode and the second electrode were arranged opposite to each other across a gap of 50 microns. An electrolysis solution was injected into the gap between the first electrode and the second electrode. The electrolysis solution is prepared by dissolving 0.2 g of ruthenium (II) trisbipyridyl (PF₆⁻)₂ as a luminous dye in 1.1 g of acetonitrile.

An injection port for the electrolysis solution was sealed with epoxy resin. Then, the first electrode was negative and the second electrode was positive, a voltage of 3V was applied, and a current was supplied. In this case, light was emitted in a quantity of 450 cd/m².

### EXAMPLE 19

<Fabrication of First Electrode and Porous Layer>

A nickel plate of 1 mm in thickness was prepared as a first electrode. On the first electrode, Nanoxide D, titania paste manufactured by Solaronix in Switzerland, was applied in a gap of 50 microns. The resultant was then dried and baked for 30 minutes at 450° C., and the process was repeated four times to obtained a porous titania film of 20 microns in thickness as a porous layer.

<Fabrication of Second Electrode>

On a glass substrate, a fluorine-doped tin oxide thin film (sheet resistance of 6Ω/sq) was formed, and a counter electrode (second electrode) of 1 mm in thickness was prepared.

The fluorine-doped tin oxide thin film of the second electrode was set opposite to the porous layer side of the first electrode, and ionomer resin Himilan 1702 (film thickness of about 50 μm) was interposed therebetween as a spacer, so that the first electrode and the second electrode were arranged opposite to each other across a gap of 50 microns. The same electrolyte as explained in Example 18 was injected into the gap between the first electrode and the second electrode.

An injection port for the electrolysis solution was sealed with epoxy resin. The first electrode was negative and the second electrode was positive, a voltage of 3V was applied, and a current was supplied. In this case, light was emitted in a quantity as shown in Table 3.

### EXAMPLE 20

A light-emitting device was fabricated in the same configuration as explained in Example 18, except that the first electrode was an Al plate of 1 mm in thickness, and the fabricated light-emitting device was evaluated in the same manner as in Example 18. Results are shown in Table 3.

### EXAMPLE 21

A light-emitting device was fabricated in the same configuration as explained in Example 18, except that the first electrode was an Al plate of 1 mm in thickness, and that a porous layer formed by anodically oxidizing the surface of the Al plate, and the fabricated light-emitting device was evaluated in the same manner as in Example 18. Results are shown in Table 3.

### EXAMPLES 22 TO 27

Light-emitting devices were fabricated in the same configuration as explained in Example 18, except that the first electrode was the substrate having the thickness and composition shown in Table 3, and the fabricated light-emitting devices were evaluated in the same manner as in Example 18. Results are shown in Table 3.

The composition of a Ni alloy in Example 26 is Ni 40% and Cu 60%, and the composition of an Al alloy in Example 27 is Al 93.5%, Cu 5%, Mn 1%, and Mg 0.5%.

### COMPARATIVE EXAMPLE 2

A light-emitting device was fabricated in the same configuration as explained in Example 18, except that the first electrode was a transparent electrode of 1 mm in thickness obtained by forming a fluorine-doped tin oxide thin film (sheet resistance of 6Ω/sq) on a glass substrate, and the fabricated light-emitting device was evaluated same as in Example 18. Results are shown in Table 3.

TABLE 3

| | First electrode | | Second electrode | | | Luminous |
|---|---|---|---|---|---|---|
| | | Thickness | | Thickness | Porous | intensity |
| | Type | (mm) | Type | (mm) | layer | (cd/m²) |
| Example 18 | Transparent | 1 | Ni plate | 1 | TiO₂ | 450 |
| | electrode | | | | | |
| Example 19 | Ni | 1 | Transparent | 1 | TiO₂ | 420 |
| | | | electrode | | | |
| Example 20 | Al | 1 | Transparent | 1 | TiO₂ | 430 |
| | | | electrode | | | |
| Example 21 | Al | 1 | Transparent | 1 | Al₂O₃ | 360 |
| | | | electrode | | | |
| Example 22 | Cu | 1 | Transparent | 1 | TiO₂ | 400 |
| | | | electrode | | | |
| Example 23 | Fe | 1 | Transparent | 1 | TiO₂ | 380 |
| | | | electrode | | | |
| Example 24 | Ag | 1 | Transparent | 1 | TiO₂ | 400 |
| | | | electrode | | | |
| Example 25 | Au | 1 | Transparent | 1 | TiO₂ | 420 |
| | | | electrode | | | |
| Example 26 | Ni alloy | 1 | Transparent | 1 | TiO₂ | 430 |
| | | | electrode | | | |
| Example 27 | Al alloy | 1 | Transparent | 1 | TiO₂ | 410 |
| | | | electrode | | | |
| Comparative | Transparent | 1 | Transparent | 1 | TiO₂ | 300 |
| example 2 | electrode | | electrode | | | |

As clear from Table 3, the light-emitting devices of Examples 18 to 27 each using a metal substrate or alloy substrate as the first electrode or second electrode are understood to be higher in luminous intensity as compared with the light-emitting device of Comparative example 2 using transparent electrodes in the first and second electrode.

By comparison of Examples 20 and 21, it is known that Example 20 having a porous layer made of TiO₂ particles is higher in luminous intensity as compared with Example 21 having a porous layer made of Al₂O₃ particles.

Among Examples 19, 20, and 22 to 27 each having a porous layer made of TiO₂ particles, a high luminous intensity of 400 cd/m² or more can be obtained in Examples 19, 20, 22, and 24 to 27 having the first electrode formed of Ni, Al, Cu, Ag, Au, Ni alloy or Al alloy.

### EXAMPLE 28

A cell already packed with an electrolysis solution but not having an injection port sealed by epoxy resin was prepared as the cell of Example 19, the cell was covered with a polyethylene film of 0.2 mm in thickness in a glove box, and the opening is sealed by heat-sealing at 200° C. The obtained light-emitting device and the cell of Example 19 having the injection port sealed by epoxy resin were heated for 500 hours in a thermostatic oven at 80° C., and the luminous intensity was measured. In this case, the luminous intensity of Example 19 was lowered to 150 cd/m², but was unchanged at 420 cd/m² in the cell of Example 28.

### EXAMPLE 29

A cell already packed with an electrolysis solution but not having an injection port sealed by epoxy resin was prepared as the cell of Example 19. The surface of the second electrode of the cell was covered with a polyethylene film of 0.2 mm in thickness in a glove box, the surface of the first electrode was covered with a laminate film of 0.2 mm, and the opening was sealed by heat-sealing at 200° C. The laminate film used was a laminate film of a polyethylene film, an Al layer, and a PET film, and the first electrode was coated such that the polyethylene film was positioned at the inner side. The obtained light-emitting device and the cell of Example 19 having the injection port sealed by epoxy resin were heated for 500 hours in a thermostatic oven at 80° C., and the luminous intensity was measured. In this case, the luminous intensity of Example 19 was lowered to 150 cd/m², but was unchanged at 420 cd/m² in the cell of Example 29.

### EXAMPLE 30

First and second electrodes were alternately arranged on a glass substrate as shown in FIG. 4. Both the first electrode and second electrode were Au electrodes, and the width of each electrode (wiring) was 100 μm, intervals of electrodes (wirings) was 10 μm, and the thickness of each electrode (wiring) was 10 μm. On the first and second electrodes, titania paste, Nanoxide HT Paste manufactured by Solaronix was applied, and a titania film of about 12 μm in thickness was formed. A glass substrate was set to the substrate oppositely across a gap, and an electrolysis solution was injected. The electrolysis solution was prepared by dissolving 0.2 g of ruthenium (II) trisbipyridyl (PF₆⁻)₂ as a luminous dye in 1.1 g of 1-ethyl-3-methyl imidazolium bis(trifluoromethyl sulfonyl)imide. After sealing, a light-emitting device having a structure shown in FIG. 3 was obtained. When an alternating-current voltage of 3V was applied, the obtained light-emitting device was proved to emit light in a quantity of 430 cd/m².

### EXAMPLE 31

A cell was manufactured in the same configuration as in Example 30, except the first and second electrodes were formed of carbon sheets. When an alternating-current voltage of 3V was applied, the obtained light-emitting device was proved to emit light in a quantity of 380 cd/m².

### COMPARATIVE EXAMPLE 32

A transparent electrode (first electrode) was prepared by forming a fluorine-doped tin oxide thin film of about 1 μm in thickness (sheet resistance of 6Ω/sq) on a glass substrate of 1000 μm in thickness.

A counter electrode (second electrode) was prepared by forming a fluorine-doped tin oxide thin film (sheet resistance of 6Ω/sq) on a glass substrate.

The fluorine-doped tin oxide thin films of the first electrode and the second electrode were set opposite to each other, and ionomer resin Himilan 1702 (film thickness of about 50 μm) was interposed therebetween as a spacer, so that the first electrode and the second electrode were arranged opposite to each other across a gap of 50 microns. An electrolysis solution was injected into the gap between the first electrode and the second electrode. The electrolysis solution was prepared by dissolving 0.2 g of ruthenium (II) trisbipyridyl (PF₆⁻)₂ as a luminous dye in 1.1 g of 1-ethyl-3-methyl imidazolium bis(trifluoromethyl sulfonyl)imide as an ionic liquid. A cation component of the ionic liquid, 1-ethyl-3-methyl imidazolium ion, has the structure shown in the above formula 2. An anion component, bis(trifluoromethyl sulfonyl)imide ion, has the structure shown in the chemical formula B.

An injection port for the electrolysis solution was sealed with epoxy resin. The first electrode was negative and the second electrode was positive, a voltage of 3V was applied, and a current was supplied. In this case, light was emitted in a quantity of 180 cd/m².

However, supposing the half-life of comparative example 1 to be 100, the half-life was 150, which was shorter than those in examples 1 to 10 and 12.

In light-emitting devices of examples 1 to 10 and 12, and comparative examples 1, 11, 13, 14 and 15, emission start voltage was measured, and results are shown in Table 4. Emission start voltage is the voltage applied when minimum unit of 1 cd/m² is provided by a luminance meter BM-8 (manufactured by Topcon).

TABLE 4

| | Emission start |
|---|---|
| | voltage (V) |
| Example 1 | 1.6 |
| Example 2 | 1.8 |
| Example 3 | 1.7 |
| Example 4 | 1.9 |
| Example 5 | 1.9 |
| Example 6 | 1.5 |
| Example 7 | 1.7 |
| Example 8 | 1.9 |
| Example 9 | 1.9 |
| Example 10 | 1.9 |
| Comparative | 2.9 |
| example 11 | |
| Example 12 | 1.6 |
| Comparative | 2.4 |
| example 13 | |
| Comparative | 2.3 |
| example 14 | |
| Comparative | 2.4 |
| example 15 | |
| Comparative | 2.7 |
| example 1 | |

As can be clearly seen from Table 4, in the light-emitting devices of examples 1 to 10 and 12 using n-type semiconductor porous layer and luminous dye containing Ru, emission start voltage was in the range of 1.5 to 2.0V.

By contrast, in the light-emitting device of comparative example 11 using luminous dye not containing Ru, light-emitting devices of comparative examples 13 and 15 using insulator in porous layer, light-emitting device of comparative example 14 using metal in porous layer, and light-emitting device of comparative example 1, the driving voltage exceeded 2.0V.

### EXAMPLE 33

A light-emitting device was manufactured in the same procedure as in example 1 except that porous film of tin oxide was used as porous layer, and was evaluated in the same way as in example 1. Results are shown in Table 5.

### EXAMPLE 34

A light-emitting device was manufactured in the same procedure as in example 1 except that porous film of zinc oxide was used as porous layer, and was evaluated in the same way as in example 1. Results are shown in Table 5.

TABLE 5

| | Luminous | | Emission |
|---|---|---|---|
| | intensity | | start |
| | at 3 V | Half- | voltage |
| | (cd/m²) | life | (V) |
| Example 33 | 300 | 220 | 1.9 |
| Example 34 | 280 | 200 | 1.9 |

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A light-emitting device comprising:
a first electrode comprising a first surface;
a second electrode comprising a second surface;
a porous layer formed of n-type semiconductor and provided on the first surface of the first electrode or the second surface of the second electrode; and
an electrolyte containing: a luminous dye containing Ru; and a molten salt including an anion component and a cation component having a structure represented by the following formula (A), the electrolyte provided between the first surface of the first electrode and the second surface of the second electrode, the electrolyte electrically contacting the first electrode and the second electrode.

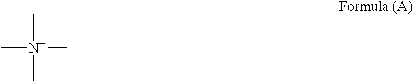

2. The light-emitting device according to claim 1, wherein the n-type semiconductor includes titania.

3. The light-emitting device according to claim 1, which has an emission start voltage of 1.5 to 2V.

4. The light-emitting device according to claim 1, wherein the first electrode or the second electrode is formed of a metal-containing substrate.

5. The light-emitting device according to claim 4, wherein the metal-containing substrate is a metal substrate made of Au, Ag, Cu, Al, Ni, or Fe, or an alloy substrate made of an alloy containing at least one metal selected from the group consisting of Au, Ag, Cu, Al, Ni, and Fe.

6. The light-emitting device according to claim 1, wherein the cation component includes at least one selected from cations having structures represented by the following chemical formulas 1 to 6: 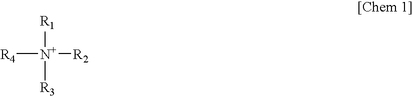
where R₁, R₂, R₃, and R₄ may be either same or mutually different, and each are an alkyl group, a phenyl group, a benzyl group, or a substituent containing C, H and O; 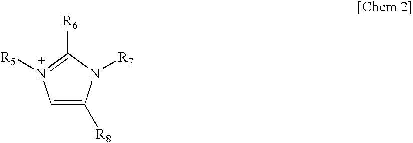
where R₅, R₆, R₇, and R₈ may be either same or mutually different, and each are an alkyl group, a substituent containing C, H and O, or a hydrogen atom; 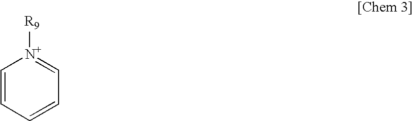
where R₉ is an alkyl group, or a substituent containing C, H and O; 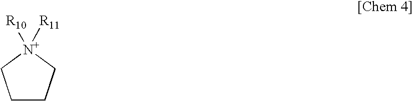
where R₁₀ and R₁₁ may be either same or mutually different, and each are an alkyl group, a phenyl group, a benzyl group, or a substituent containing C, H and O; 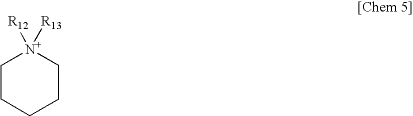
where R₁₂ and R₁₃ may be either same or mutually different, and each are an alkyl group, a phenyl group, a benzyl group, or a substituent containing C, H and O; and 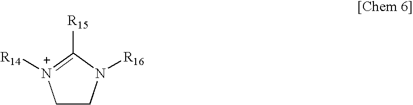
where R₁₄, R₁₅, and R₁₆ may be either same or mutually different, and each are an alkyl group, or a substituent containing C, H and O.

7. The light-emitting device according to claim 1, wherein the anion component contains F.

8. The light-emitting device according to claim 1, wherein a content of the molten salt in the electrolyte is 80 vol. % or more.

9. A light-emitting device comprising:
a first electrode comprising a first surface;
a porous layer provided on the first surface of the first electrode;
a second electrode comprising a second surface, the second surface facing the porous layer; and
an electrolyte provided between the porous layer and the second surface of the second electrode, the electrolyte electrically contacting the first electrode and the second electrode, and the electrolyte containing a luminous dye,
wherein either the first electrode or second electrode is formed of a metal-containing substrate.

10. The light-emitting device according to claim 9, wherein the first electrode is formed of the metal-containing substrate, and the second electrode is a transparent electrode.

11. The light-emitting device according to claim 9, wherein the metal-containing substrate is a metal substrate made of Au, Ag, Cu, Al, Ni, or Fe, or an alloy substrate made of an alloy containing at least one metal selected from the group consisting of Au, Ag, Cu, Al, Ni, and Fe.

12. The light-emitting device according to claim 9, wherein a thickness of the metal-containing substrate is 0.02 mm to 10 mm.

13. The light-emitting device according to claim 9, wherein the porous layer includes n-type semiconductor particles.

14. The light-emitting device according to claim 9, wherein the luminous dye contains Ru.

15. A light-emitting device comprising:
a film container;
a first electrode provided in the container and comprising a first surface;
a second electrode comprising a second surface; and
an electrolyte containing: a luminous dye; and a molten salt including an anion component and a cation component having a structure represented by the following formula (A), the electrolyte provided between the first surface of the first electrode and the second surface of the second electrode, the electrolyte electrically contacting the first electrode and the second electrode.

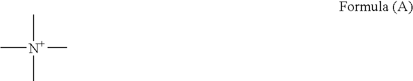

16. The light-emitting device according to claim 15, which comprises a porous layer formed of n-type semiconductor and provided on the first surface of the first electrode or the second surface of the second electrode, and the luminous dye contains Ru.

17. The light-emitting device according to claim 15, wherein the container comprises a transparent thermoplastic resin film surface and a laminate film surface containing an Al layer or Al alloy layer.

18. The light-emitting device according to claim 17, wherein the transparent thermoplastic resin film surface of the container faces the first electrode or the second electrode.

19. A light-emitting device comprising:
a film container;
a first electrode provided in the film container and comprising a first surface;
a porous layer provided on the first surface of the first electrode;
a second electrode comprising a second surface, the second surface facing the porous layer; and
an electrolyte provided between the porous layer and the second surface of the second electrode, the electrolyte electrically contacting the first electrode and the second electrode, and the electrolyte containing a luminous dye,
wherein either the first electrode or second electrode is formed of a metal-containing substrate.

20. The light-emitting device according to claim 19, wherein the container comprises a transparent thermoplastic resin film surface and a laminate film surface containing an Al layer or Al alloy layer.
